(19) United States
(12) Patent Application Publication
(10) Pub. No.: US 2026/0118207 A1
(43) Pub. Date: Apr. 30, 2026

(54) ACOUSTIC LEAK DETECTION IN LIQUID COOLING SYSTEMS

(71) Applicant: DELL PRODUCTS L.P., Round Rock, TX (US)

(72) Inventors: Bhyrav Mutnury, Round Rock, TX (US); Michael Stumpf, Cedar Park, TX (US); Sandor Farkas, Round Rock, TX (US)

(21) Appl. No.: 18/927,952

(22) Filed: Oct. 26, 2024

(51) Int. Cl. G01M 3/24; H05K 7/20

(52) U.S. Cl. CPC G01M 3/243; H05K 7/20272; H05K 7/20781

(57) ABSTRACT

An apparatus includes a first microphone, a second microphone, and a signal processing circuit. The first microphone is attached to a first location on a hose transporting cooling liquid and is configured to generate a first analog signal. The second microphone is attached to a second location on the hose and is configured to generate a second analog signal. The signal processing circuit is coupled to the first and second microphones and is configured to detect a leak on the hose between the first and second locations based on a correlation signal between the first and second analog signals over a time window. The first and second analog signals represent sound waves caused by the leak and flow of the cooling liquid through the hose at the first and second locations.

### FIELD OF THE DISCLOSURE

This disclosure generally relates to information handling systems, and more particularly relates to acoustic leak detection in liquid cooling systems.

### BACKGROUND

As the value and use of information continues to increase, individuals and businesses seek additional ways to process, store, and display information. One option is an information handling system. An information handling system generally processes, compiles, stores, communicates and/or display information or data for business, personal, or other purposes. Because technology and information handling needs and requirements may vary between different applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, reservations, enterprise data storage, or global communications. In addition, information handling systems may include a variety of hardware and software resources that may be configured to process, store, display, and communicate information and may include one or more computer systems, data storage systems, and networking systems.

### SUMMARY

An apparatus includes a first microphone, a second microphone, and a signal processing circuit. The first microphone is attached to a first location on a hose transporting cooling liquid and is configured to generate a first analog signal. The second microphone is attached to a second location on the hose and is configured to generate a second analog signal. The signal processing circuit is coupled to the first and second microphones and is configured to detect a leak on the hose between the first and second locations based on a correlation signal between the first and second analog signals over a time window. The first and second analog signals represent sound waves caused by the leak and flow of the cooling liquid through the hose at the first and second locations.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1 is a diagram illustrating an information handling system according to an embodiment of the present disclosure

FIG. 2 is a block diagram illustrating a server system according to an embodiment of the present disclosure;

FIG. 3 is a diagram illustrating an acoustic leak detector according to an embodiment of the present disclosure;

FIG. 4 is a diagram illustrating a signal processing circuit according to an embodiment of the present disclosure;

FIGS. 5A, 5B, and 5C are diagrams illustrating the leak detection result when there is no leak according to an embodiment of the present disclosure;

FIGS. 6A, 6B, and 6C are diagrams illustrating the leak detection result when there is a leak according to an embodiment of the present disclosure; and

FIG. 7 is a flowchart illustrating a process for acoustic leak detection according to an embodiment of the present disclosure.

The use of the same reference symbols in different drawings indicates similar or identical items.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings, and should not be interpreted as a limitation on the scope or applicability of the teachings. However, other teachings can certainly be used in this application. The teachings can also be used in other applications, and with several different types of architectures, such as distributed computing architectures, client/server architectures, or middleware server architectures and associated resources.

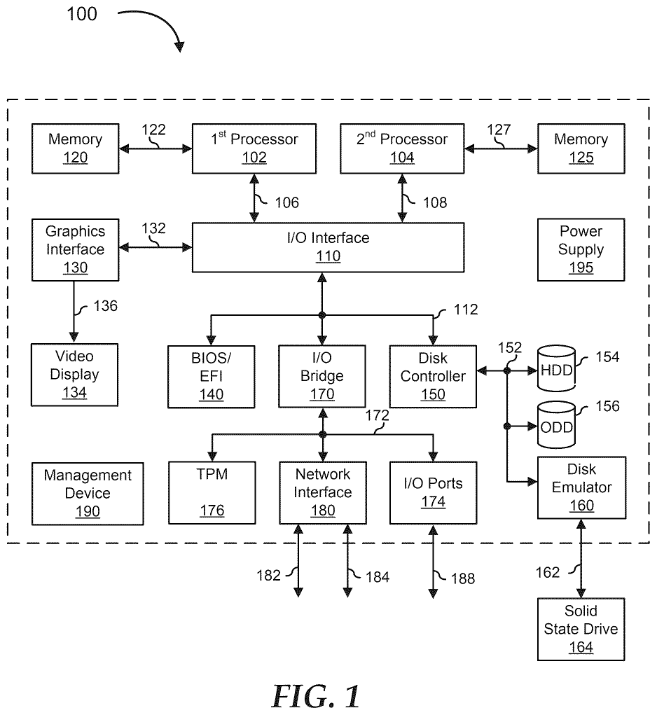

FIG. 1 shows an information handling system 100.

For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. The term “information handling system” may refer to a processing system, a control circuit, a control processor, or any processing apparatus that processes or handles information, data, or control or status words. For example, information handling system 100 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 100 can include processing resources for executing machine-executable code, such as a central processing unit (CPU), a programmable logic array (PLA), an embedded device such as a System-on-a-Chip (SoC), or other control logic hardware. Information handling system 100 can also include one or more computer-readable medium for storing machine-executable code, such as software or data. Additional components of information handling system 100 can include one or more storage devices that can store machine-executable code, one or more communications ports for communicating with external devices, and various input and output (I/O) devices, such as a keyboard, a mouse, and a video display. Information handling system 100 can also include one or more buses operable to transmit information between the various hardware components.

Information handling system 100 can include devices or modules that embody one or more of the devices or modules described in this disclosure, and operates to perform one or more of the methods described in this disclosure. Information handling system 100 may include more or less than the components described in the following. Information handling system 100 includes first and second processors 102 and 104, an input/output (I/O) interface 110, memories 120 and 125, a graphics interface 130, a basic input and output system/universal extensible firmware interface (BIOS/UEFI) module 140, a disk controller 150, a hard disk drive (HDD) 154, an optical disk drive (ODD) 156, a disk emulator 160 connected to an external solid state drive (SSD) 164, an I/O bridge 170, one or more add-on resources 174, a trusted platform module (TPM) 176, a network interface 180, a management device 190, and a power supply 195. Processors 102 and 104, I/O interface 110, memory 120, graphics interface 130, BIOS/UEFI module 140, disk controller 150, HDD 154, ODD 156, disk emulator 160, SSD 164, I/O bridge 170, add-on resources 174, TPM 176, and network interface 180 operate together to provide a host environment of information handling system 100 that operates to provide the data processing functionality of the information handling system. The host environment operates to execute machine-executable code, including platform BIOS/UEFI code, device firmware, operating system code, applications, programs, and the like, to perform the data processing tasks associated with information handling system 100.

In the host environment, processor 102 is connected to I/O interface 110 via processor interface 106, and processor 104 is connected to the I/O interface via processor interface 108. Memory 120 is connected to processor 102 via a memory interface 122. Memory 125 is connected to processor 104 via a memory interface 127. Graphics interface 130 is connected to I/O interface 110 via a graphics interface 132, and provides a video display output 136 to a video display 134. In a particular embodiment, information handling system 100 includes separate memories that are dedicated to each of processors 102 and 104 via separate memory interfaces. An example of memories 120 and 125 include random access memory (RAM) such as static RAM (SRAM), dynamic RAM (DRAM), non-volatile RAM (NV-RAM), or the like, read only memory (ROM), another type of memory, or a combination thereof. Processor 102 and/or processor 104 may process data or information to be displayed on a monitor.

BIOS/UEFI module 140, disk controller 150, and I/O bridge 170 are connected to I/O interface 110 via an I/O channel 112. An example of I/O channel 112 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 110 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 140 includes code that operates to detect resources within information handling system 100, to provide drivers for the resources, to initialize the resources, and to access the resources.

Disk controller 150 includes a disk interface 152 that connects the disk controller to HDD 154, to ODD 156, and to disk emulator 160. An example of disk interface 152 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 160 permits SSD 164 to be connected to information handling system 100 via an external interface 162. An example of external interface 162 includes a USB interface, an IEEE 1394 (Firewire) interface, a proprietary interface, or a combination thereof. Alternatively, solid-state drive 164 can be disposed within information handling system 100.

I/O bridge 170 includes a peripheral interface 172 that connects the I/O bridge to I/O port or add-on resource 174, to TPM 176, and to network interface 180. Peripheral interface 172 can be the same type of interface as I/O channel 112 or can be a different type of interface. As such, I/O bridge 170 extends the capacity of I/O channel 112 where peripheral interface 172 and the I/O channel are of the same type, and the I/O bridge translates information from a format suitable to the I/O channel to a format suitable to the peripheral channel 172 where they are of a different type. I/O port 174 can include I/O lines to interface to a parallel or serial I/O channel, a data storage system, an additional graphics interface, a network interface card (NIC), a sound/video processing card, another add-on resource, or a combination thereof. I/O port 174 can be on a main circuit board, on separate circuit board or add-in card disposed within information handling system 100, a device that is external to the information handling system, or a combination thereof.

Network interface 180 represents a NIC disposed within information handling system 100, on a main circuit board of the information handling system, integrated onto another component such as I/O interface 110, in another suitable location, or a combination thereof. Network interface device 180 includes network channels 182 and 184 that provide interfaces to devices that are external to information handling system 100. In a particular embodiment, network channels 182 and 184 are of a different type than peripheral channel 172 and network interface 180 translates information from a format suitable to the peripheral channel to a format suitable to external devices. An example of network channels 182 and 184 includes InfiniBand channels, Fibre Channel channels, Gigabit Ethernet channels, proprietary channel architectures, or a combination thereof. Network channels 182 and 184 can be connected to external network resources (not illustrated). The network resource can include another information handling system, a data storage system, another network, a grid management system, another suitable resource, or a combination thereof.

Management device 190 represents one or more processing devices, such as a dedicated baseboard management controller (BMC), System-on-a-Chip (SoC) device, one or more associated memory devices, one or more network interface devices, a complex programmable logic device (CPLD), and the like, that operate together to provide the management environment for information handling system 100. In particular, management device 190 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 100, such as system cooling fans and power supplies. Management device 190 can include a network connection to an external management system, and the management device can communicate with the management system to report status information for information handling system 100, to receive BIOS/UEFI or system firmware updates, or to perform other task for managing and controlling the operation of information handling system 100. Management device 190 can operate off of a separate power plane from the components of the host environment so that the management device receives power to manage information handling system 100 where the information handling system is otherwise shut down. An example of management device 190 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 190 may further include associated memory devices, logic devices, security devices, or the like, as needed or desired.

Information handling systems are increasingly complex. To meet demands for high performance, information handling systems are packed with a large amount of semiconductor chips, computing circuits, and many peripheral and interfacing elements. Such systems typically consume a lot of power and generate excessive heat that may cause diminished quality and even damage to the systems. To reduce heat, cooling techniques have been developed. Among various cooling techniques, liquid cooling has been increasingly popular due to its energy efficiency, performance effectiveness, and low cost. Liquid cooling techniques, however, may create problems such as leaks. Leak detection, control and management, therefore, is useful to maintain the integrity of the cooling system in high computing environments such as complex information handling systems, artificial intelligence (AI) platforms, and data centers.

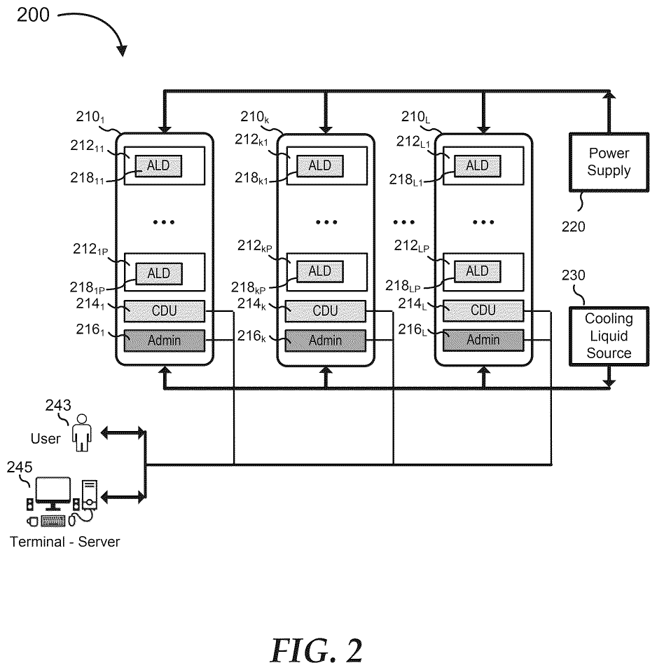

FIG. 2 shows a server system 200 according to an embodiment of the present disclosure. The server system 200 may be a multiprocessor computer system, a high performance computing (HPC) system, a large network center, a cluster of servers, a data center, an artificial intelligence (AI) system, edge computing, cloud computing, network servers, or any large electronic systems with high power consumption. The server system 200 may include part or all of the information handling system 100 shown in FIG. 1. The server system 200 typically employs thousands of semiconductor devices such as central processing units (CPUs), graphical processing units (GPUs), and memory chips. The server system 200 may include L rack, or rack-mounted, servers 210ₖ's, where k=1, . . . , L, a power supply 220, and a cooling liquid source 230. L is a positive integer with a value depending on the configuration of the system 200. The system 200 may include more or less than the above components. In the following, the subscript index k may be dropped for clarity.

The L rack servers 210ₖ's may be located in a single room, in several rooms, or scattered throughout a building, on the same floor or on different floors. The system 200 may have identical L rack servers 210ₖ's for illustrative purposes only. They may be the same or have different configurations. They may be part of clusters of processors in a highly parallel system or they may be established for specific applications such as medical, scientific research, or business enterprise. As an example, a server may be dedicated to intensive computing, another may serve to store data, yet another may focus on graphical display and animation. They may work as standalone subsystems or connected to one another via a local area network (LAN) or wide area network (WAN). The L rack servers 210ₖ's represent an example of an HPC system. The system 200 may include components that are packaged or assembled in any convenient format, and not necessarily to be mounted on racks, slots, or bays. The L rack servers 210ₖ's typically consume a large amount of power during active periods. Because of this high power consumption, the L rack servers 210ₖ's generate an excessive amount of heat. Accordingly, a cooling technique is employed to cool the system and to prevent overheating that may cause performance degradation or damage to the system. In one embodiment, the cooling technique used in the system 200 is liquid cooling.

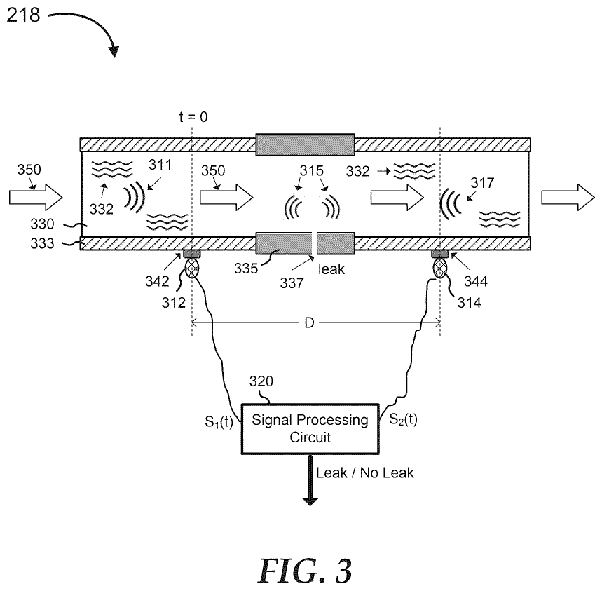

Each of the L rack servers 210ₖ's includes a number of servers 212ₖⱼ's where k=1, . . . , L and j=1, . . . , P (P is a positive integer having a predetermined value), a cooling distribution unit (CDU) 214; and an administration server 216ₖ. The servers 212ₖⱼ's are mounted on slots in the rack or cabinet. In this illustrative example, a server is typically designed for continuous and heavy use. Each server may be populated with electronic devices such as CPUs, memories, storage, and peripheral devices. They may also include network switches, cable management systems, and appropriate mounting hardware. Each of the servers 212ₖⱼ's may include an acoustic leak detector (ALD) 218ₖⱼ. The ALD detects leaks in the hose using an acoustic signal processing technique. The ALD 218ₖⱼ will be described in FIG. 3.

The CDU 214 distributes coolant throughout the rack server 210ₖ. It may include a pumping mechanism to circulate the coolant to the heat-generating components or cold plates placed on top of CPUs or GPUs. The CDU 214 may operate together with coolant distribution manifolds (CDMs). The CDMs are distribution pipes that supply coolant to each server and collect the hotter coolant back to the CDU. Flexible hoses are used to carry the cooler liquid to the individual server at the ingress to the various sites on the server and return the hotter liquid to the associated CDM at the egress. These hoses are connected through various connectors and valves.

The administration server 216; includes circuits that perform administration of the cooling policies and implementations. The administration includes the central control, management, and regulation of various components, subsystems, or system in the system 200. The administration server 216ₖ may communicate with the ALD 218ₖⱼ to receive a leak detection status. It may also interact with a user 243 and/or a terminal or server 245. The user 243 may be any individual or entity responsible for the administration of the individual server in the L rack servers 210ₖ's or the system 200. The user 243 may receive status reports or alerts from the administration server 216ₖ and respond with commands or instructions to the administration server 216ₖ. The terminal or server 245 may include a processing circuit, software, or an application that has been designed to automatically respond to reports or alerts from the administration server 216ₖ.

The power supply 220 provides power to the L rack servers 210ₖ's in addition to other power needs for the facilities including lighting, cooling (e.g., air-conditioning), network load. The power supply 220 may include a typical power infrastructure including transformers, power distribution units (PDUs), power breakers, uninterruptible power supplies (UPSes), and backup generators.

The cooling liquid source 230 may include any suitable sources for liquid cooling including water and dielectric fluids. It may include coolant distribution units (CDUs), liquid cooled racks, indoor chilled water storage, and pumps. The cooling type may be direct-to-chip cooling and rear-door liquid cooling. In one embodiment, the system 200 utilizes the direct-to-chip cooling technique in which the cooling mechanisms are applied directly to the heat-generating components such as CPUs, GPUs, and memory chips. The cooling liquid source 230 delivers the coolant to each of the L rack servers 210ₖ's via the CDU 214ₖ's and CDMs.

FIG. 3 shows the acoustic leak detector 218. For clarity, subscripts may be dropped. The acoustic leak detector 218 includes a first microphone 312, a second microphone 314, and a signal processing circuit 320. The acoustic leak detector 218 may include more or less than the above components.

The first microphone 312 is attached to, mounted on, fastened to, or secured on a hose wall 333 of a hose 330 at a first location 342. The first location 342 marks the location where the signal processing starts. The time is set t=0 at this location. The hose or a tubular device 330 transports cooling liquid 332 through sites in a computing environment such as the rack servers 210. The first microphone 312 is configured to generate a first analog signal S₁(t). Similarly, the second microphone 314 is attached to, mounted on, fastened to, or secured on the hose wall 333 of the hose 330 at a second location 344. The second microphone 312 is configured to generate a second analog signal S₂(t). The first and second locations 342 and 344 are selected to provide reliable signals suitable for signal processing and analysis such as locations having a high risk of leak (e.g., fittings). In one embodiment the first location 342 is upstream and the second location 344 is downstream. D is the distance between the two locations.

In one embodiment, the first and second locations 342 and 344 are selected near places where the hose 330 is susceptible to leakage. The first and second analog signals S₁(t) and S₂(t) represent sound waves caused by flow of the cooling liquid 332 through the hose 330 at the first and second locations 342 and 344. The flow 350 of the cooling liquid 332 through the hose 330 generates sounds that are primarily caused by turbulence and vibrations. The turbulence and vibrations are created by the movement of the cooling liquid. As the cooling liquid flows through the hose, it encounters friction along the hose wall 333 which leads to turbulence. In addition, due to the geometry of the pathway along which the hose 330 is shaped, there may be localized regions of pressure differentials which further generate sound waves.

The hose 330 has a hose fitting 335 encompassing the hose wall 333. Suppose there is a leak 337 characterized by a crack at the hose fitting 335. The leak 337 causes a form of turbulence that modifies the normal flow of the cooling liquid and the resulting sound waves along the hose 330 in the vicinity of the leak 337. At the first location 342, the flow 350 of the cooling liquid generates sound waves 311. At the second location 344, the flow 350 of the cooling liquid generates sound waves 317. At the location of the leak 337, the flow 350 of the cooling liquid generates sound waves 315. The sound waves 311 generate the same acoustic signal on both microphones 312 and 314. Similarly, the sound waves 317 generate the same acoustic signal on both microphones 312 and 314. The sound waves 315 are generated at the leak 337 in both directions, but because of the fluid flow, there is Doppler effect at play and the upstream microphone 312 will see a lower frequency and the downstream microphone 314 will see a higher frequency.

The signal processing circuit 320 is coupled to the first and second microphones to receive the first and second analog signals S₁(t) and S₂(t). The signal processing circuit 320 is configured to detect the leak 337 on the hose 330 between the first and second locations 342 and 344 based on a correlation signal between the first and second analog signals S₁(t) and S₂(t) over a time window. In one embodiment, the leak 337 is shown to be located at the fitting 335 because the fitting 335 is likely to have leaks. In other embodiments, the leak 337 may occur anywhere between the first and second locations 342 and 344. The correlation is actually performed on the digital, or sampled, versions of the first and second analog signals S₁(t) and S₂(t). The digital signals are obtained by sampling the first and second analog signals S₁(t) and S₂(t) at two different sampling rates. This process effectively undoes the Doppler shift from the leak noise and applies the opposite Doppler shift to the flow noise. Then, the correlation will be performed on these digital signals to reject the now shifted and therefore uncorrelated flow noise and detects the now correlated leak noise. In a way, the process uses the Doppler shift as modulation and uses the sampling rate for demodulation.

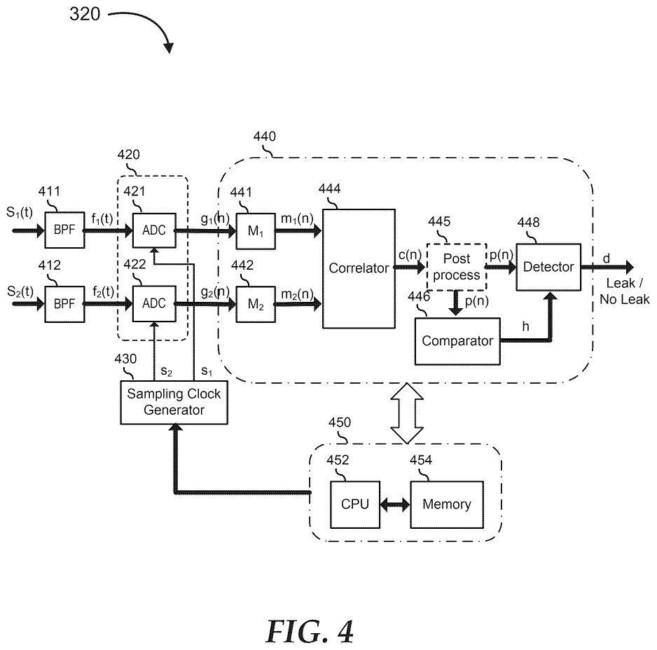

FIG. 4 shows the signal processing circuit 320 according to an embodiment of the present disclosure. The signal processing circuit 320 receives the signals S₁(t) and S₂(t) as inputs and generates a signal d as output. It includes first and second bandpass filters (BPFs) 411 and 412, an analog-to-digital converter (ADC) 420, a sampling clock generator 430, a functionality module 440, and a processing system 450. The signal processing circuit 320 may include more or less than the above components.

The signals S₁(t) and S₂(t) may need to be filtered to remove any unwanted frequencies. This may be done by an analog filter or a digital filter. If an analog filter is used, the filtering is done prior to the analog-to-digital conversion. If a digital filter is used, the filtering is done after the analog-to-digital conversion. The choice between the analog and digital filters depends on factors such as power, aliasing considerations, latency, noise, etc. The BPFs 411 and 412 are analog bandpass filters. They filter the signals S₁(t) and S₂(t) at a bandpass frequency range up to a predetermined bandpass frequency to remove unwanted noise signals. In one embodiment, the predetermined bandpass frequency may be 5 KHz. The BPFs 411 and 412 generate filtered signals f₁(t) and f₂(t), respectively.

The ADC 420 is a dual-channel ADC having two separate ADCs 421 and 422. The ADCs 421 and 422 are configured to perform analog-to-digital conversion on the signals f₁(t) and f₂(t) at first and second sampling rates s₁ and s₂, respectively, to produce the digital signals g₁(n) and g₂(n), respectively. Each of the ADCs 421 and 422 may include a sample-and-hold circuit to hold the signal constant during conversion.

The sampling clock generator 430 is configured to generate the first and second sampling clock signals having the sampling rates s₁ and s₂ based on a speed of sound (c) and a flow velocity (vf) of the cooling liquid. The term “sampling clock” and “sampling rate” may be used interchangeably to refer to a sampling rate or a clock signal having the specified sampling rate. The flow velocity vf may be determined based on the flow rate, the volume of the liquid, and the distance traveled. In one embodiment, the initial estimate for the flow velocity vf may be determined from the flow rate and the tube cross section or measured with a flow meter. The sampling clock generator 430 may be controlled by the processing system 450. In one embodiment, the sampling clocks are determined as follows:

$${s}_{1} = clk \frac{c - v f}{c + v f} \qquad ( 1 )$$

$${s}_{2} = clk \frac{c + v f}{c - v f} \qquad ( 2 )$$

where clk is a clock reference that is used to create the upshifted and downshifted sample rates. Both s₁ and s₂ comply with the Nyquist criteria.

In other words, the first sampling rate s₁ is equal to the default sampling rate clk weighed by a first factor equal to (c−vf)/(c+vf) and the second sampling rate s₂ is equal to the default sampling rate clk weighed by a second factor equal to (c+vf)/(c−vf). The equations (1) and (2) are derived based on the Doppler shift as a result of the sound waves propagated in the hose 330. The sound waves propagated in both directions toward the locations 342 and 344 shown in FIG. 3.

The functionality module 440 performs a number of functions as part of the leak detection. It may include hardware components or software functions or a combination of hardware and software. When it includes software functions, these functions may be performed by the processing system 450. When it includes hardware components, the processing system 450 may still be employed to perform various control and administrative functions. The functionality module 440 includes first and second memories 441 and 442, a correlator 444, a post processor 445, a comparator 446, and a detector 448. The functionality module 440 may include more or less than the above components.

The first and second memories 441 and 442 are configured to store the digital signals g₁(n) and g₂(n), respectively, and generate the stored signals as m₁(n) and m₂(n), respectively. Therefore, m₁(n) and m₂(n) represent the S₁(t) and S₂(t) signals. The size of the memories is sufficient to store the digital data over the time window. In one embodiment, the first and second memories 441 and 442 are implemented as random access memory (RAM), the RAM may be static or dynamic.

The correlator 444 reads the digital data samples or signals m₁(n) and m₂(n) from the first and second memories 441 and 442, respectively, and calculates the correlation signal between the signal m₁(n) and m₂(n). Because S₁(t) and S₂(t) may be delayed from each other due to the random location of the leak relative to the microphones, the process calculates the full correlation.

The calculation of the correlation may be performed in the time domain or frequency domain. In one embodiment, this is done using the Fast Fourier Transform (FFT), resulting in a set of numbers which represents the correlation at each delay element. The maximum number from that set represents the correlation magnitude and the location within the set represents the delay.

The correlation magnitude indicates whether a leak exists. If it exceeds a threshold, a leak exists. Otherwise, there is no leak. The threshold may be determined by experiments or tests.

The post processor 445 performs post processing operations if desired. Its use is optional. Examples of the post processing operations include smoothing, sliding window, averaging, interpolation, extrapolation, filtering, etc. The objective of the post-processing operations is to enhance the correlation so that reliable detection can be achieved.

The comparator 446 compares the correlation signal c(n) with one or more predetermined threshold. One threshold is the peak threshold which is the threshold used to compare with the peak of the correlation signal c(n) or the correlation magnitude as mentioned above. As above, when the correlation magnitude exceeds the threshold, the interpretation is that there is a leak. The peak is narrow if there is a strong correlation. The peak is broad if the leak is small or when s₁ and s₂ do not completely cancel out the Doppler shift. This may happen when the flow rate changes over time. The measurement may be iterated with small adjustments to s₁ and s₂ to optimize the height and the width of the peak.

The detector 448 may perform the decision regarding whether there is a detected leak on the hose 330. In one embodiment, the detector 448 includes the comparator 446 or makes a decision based on the result of the comparator 446. If the peak of the correlation signal c(n) exceeds the threshold, it is decided that there is a leak. Other parameters may be taken into account including the width of the correlation signal c(n) (e.g., the number of samples of c(n) exceeding the threshold), the magnitude of the peak, the persistence of the leak decision over a time period. For example, once a leak is determined, the process may be repeated again for a number of times to determine if the result persists. Other considerations may also be included. For example, if there are more than one leak detector installed, the results of these leak detectors can be analyzed and examined to determine if they are consistent with a leak.

The processing system 450 may perform general control and administrative tasks including communication with other parts of the system 200 and user interface. It may include a programmable processor or a central processing unit (CPU) 452 and a memory 454. The memory 454 may store instructions or programs that, when executed by the CPU 452, cause the CPU 452 to perform operations as described in connection with the functionality module 440. In one embodiment, the processing system 450 may perform all or parts of the functions of the functional module 440 in a software-oriented manner. In particular, the processing system 450 may calculate the correlation signal c(n) by executing a program or a function. The processing system 450 may be part of an information handling system 100 that oversees the system 200 or the server 210 (shown in FIG. 2). It may have input/output (IO) channels to control various devices in the system. It may control the sampling clock generator 430 including calculating the sampling rates and activating the clock generator to generate the sampling clock s₁ and s₂.

### Leak Detection Using Correlation

The leak detection using correlation is a procedure based on the Doppler effect. Referring to FIG. 3, let n1 be the downstream sound waves 311 as ambient noise in the cooling liquid at the first location 342. Let n2 be the upstream soundwaves 317 at the second location 344. Let n3 be the leak-related noise in fluid caused by the leak 337. When there is a leak, each of the signals S₁(t) and S₂(t) is the sum of the downstream and upstream sound waves from the first, second, and leak locations. When there is no leak, each of the signals S₁(t) and S₂(t) is the sum of the downstream and upstream sound waves from the first and second locations. n1 and n2 are sound waves from the same cooling liquid and therefore are common mode noise and are correlated. They can be made uncorrelated by sampling the signals S₁(t) and S₂(t) at two different sampling rates. On the other hand, n3 represents sound waves from the leak location 337 traveling to the first and second locations 342 and 344 in opposite directions. Therefore, the signal n3 at the first and second locations are uncorrelated due to the Doppler effect that causes the shifting in frequency. To undo the Doppler effect, the signal n3 at the first and second locations are sampled at two different sampling rates. The result is that these two signals become correlated. Accordingly, after sampling, S₁(t) and S₂(t) are highly correlated if there is a leak and are highly uncorrelated if there is no leak.

Due to the Doppler effect, the frequency shift at downstream is (c+vf)/(c−vf) and the frequency shift at upstream is (c−vf)/(c+vf) where c is the speed of sound, vf is the flow velocity. Therefore, the sampling rates s1 and s2 that would cause the signals n1 and n2 at the two locations 342 and 344, respectively, to become uncorrelated and at the same time cause the signals n3 at the two locations 342 and 344 to become correlated are:

$$s 1 = clk * ( c - vf ) / ( c + vf ) \qquad ( 3 )$$

$$s 2 = clk * ( c + vf ) / ( c - v f ) \qquad ( 4 )$$

where clk is the clock reference. The result of the sampling is the introduction of a frequency shift Δf component.

There are two cases: when there is no leak and when there is leak.

Correlation when there is No Leak

When there is no leak, there is no signal n3. The signals S₁(t) and S₂(t) contain only the n1 and n2 components. Before sampling, S₁(t) and S₂(t) are:

$${S}_{1} ( t ) = n 1 ( 2 π f ) + n 2 ( 2 π f ) \qquad ( 5 )$$

$${S}_{2} ( t ) = n 1 ( 2 π f - ϕ ) + n 2 ( 2 π f + ϕ ) \qquad ( 6 )$$

where f is the original signal frequency, and φ is the phase shift due to the wave traveling through the distance between the two microphones.

After sampling, S₁(t) and S₂(t) become:

$${S}_{1} ( t ) = n 1 ( 2 π ( f + Δ f ) ) + n 2 ( 2 π ( f + Δ f ) ) \qquad ( 7 )$$

$${S}_{2} ( t ) = n 1 ( 2 π ( f - Δ f ) - ϕ ) + n 2 ( 2 π ( f - Δ f ) + ϕ ) \qquad ( 8 )$$

where Δf is what the Doppler shift would be if there was a sound going in both directions. In this case, since there is no leak, there is no Doppler shift.

It can be seen from equations (7) and (8) that the n1 components in S₁(t) and S₂(t) are uncorrelated due to the difference in the frequency shift (+Δf in S₁(t) and −Δf in S₂(t)). Similarly, the n2 components in S₁(t) and S₂(t) are uncorrelated due to the difference in the frequency shift. Therefore, a correlation between S₁(t) and S₂(t) after sampling results in a very low correlation value. Another way to say this is that a low correlation value between S₁(t) and S₂(t) after sampling, or m₁(n) and m₂(n), indicates that there is no leak.

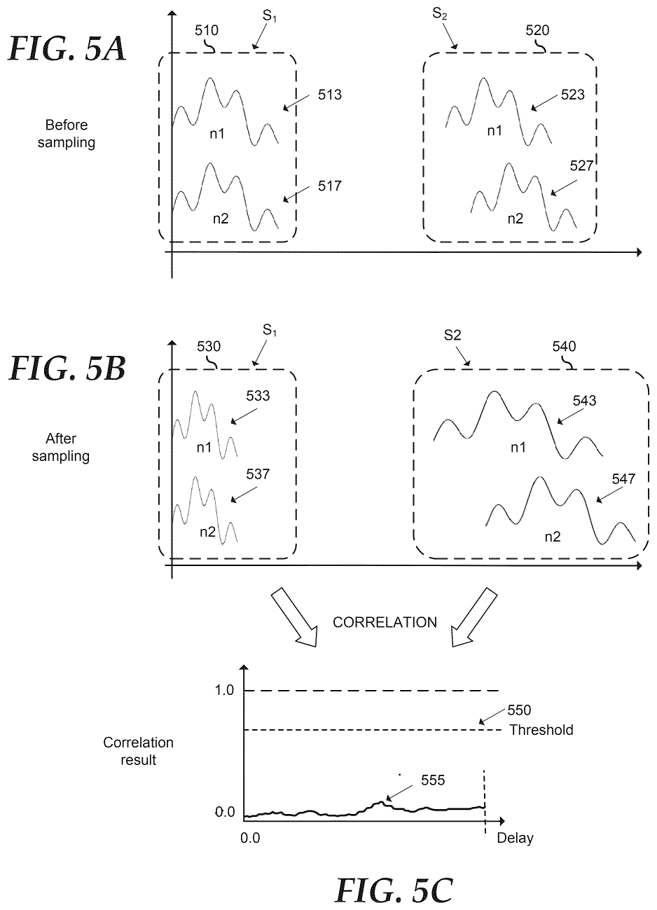

FIGS. 5A, 5B, and 5C show the leak detection result when there is no leak according to an embodiment of the present disclosure. FIG. 5A illustrates the signals before sampling. FIG. 5B illustrates the signals after sampling. FIG. 5C illustrates the correlation result.

In FIG. 5A, the signal S₁ 510 is the sum of the signal n1(2πf) 513 and the signal n2(2πf) 517 as shown in equation (5). The signal S₂ 520 is the sum of the signal n1(2πf−φ) 523 and n2(2πf+φ) 527 as shown in equation (6). They differ mainly by a phase shift and therefore their shapes are essentially the same. In other words, they are still correlated.

In FIG. 5B, the signal S₁ 530 is the sum of the signal n1(2π(f+Δf)) 533 and the signal n2(2π(f+Δf)) 537 as shown in equation (7). Due to the sampling by s₁, the signals n1(2π(f+Δf)) and n2(2π(f+Δf)) are compressed. The signal S₂ 540 is the sum of the signal n1(2π(f−Δf)−φ) 543 and n2(2π(f−Δf)+φ) 547 as shown in equation (8). Due to the sampling by s₂, the signals n1(2π(f−Δf)−φ) and n2(2π(f−Δf)+φ) are stretched. Therefore, n1(2πf) and n1(2π(f−Δf)−φ) have markedly different shapes and therefore they are uncorrelated. Similarly, n2(2πf) and n2(2π(f−Δf)++) have markedly different shapes and therefore they are uncorrelated.

In FIG. 5C, the correlation between S1 530 and S2 540 is calculated over a sliding window and the result is compared with a threshold 550. The ordinate or vertical axis represents the correlation value. The abscissa or horizontal axis represents the delay between the two microphones. The threshold 550 is a predetermined value that may be obtained through experiments and/or tests. The correlation result is a signal 555 with a very low value, much below the threshold 550. Since the correlation is much below the threshold, the leak detector declares that there is no leak and no alert is sent.

Correlation when there is a Leak

When there is a leak, the signal n3 occurs. The signals S₁(t) and S₂(t) contain all three components: n1, n2, and n3 components. Before sampling, S₁(t) and S₂(t) are:

$${S}_{1} ( t ) = n 1 ( 2 π f ) + n 2 ( 2 π f ) + n 3 ( 2 π ( f - Δ f 1 ) \qquad ( 9 )$$

$${S}_{2} ( t ) = n 1 ( 2 π f - ϕ ) + n 2 ( 2 π f + ϕ ) + n 3 ( 2 π ( f + Δ f 1 ) \qquad ( 10 )$$

where f is the original signal frequency and φ is the phase shift due to the wave traveling.

After sampling, S₁(t) and S₂(t) become:

$${S}_{1} ( t ) = n 1 ( 2 π ( f + Δ f ) ) + n 2 ( 2 π ( f + Δ f ) ) + n 3 ( 2 π f ) \qquad ( 11 )$$

$${S}_{2} ( t ) = n 1 ( 2 π ( f - Δ f ) - ϕ ) + n 2 ( 2 π ( f - Δ f ) + ϕ ) + n 3 ( 2 π f ) \qquad ( 12 )$$

where Δf the frequency shift due to the Doppler effect.

As in the case of no leak, the n1 and n2 components become uncorrelated. In contrast, the n3 components become correlated because the sampling rates s1 and s2 restore the signals or undo the Doppler effect. Accordingly, S₁(t) and S₂(t) contain signals that are highly correlated due to the n3 component, which is from the leak. Therefore, a correlation between S₁(t) and S₂(t) after sampling results in a very high correlation value. Another way to say this is that a high correlation value between S₁(t) and S₂(t) after sampling, or m₁(n) and m₂(n), indicates that there is a leak. To ensure reliable detection, the detection may include not just the comparison of the peak of the correlation with a predetermined threshold, but also the size of the width of the correlation signal, which reflects the correlation over a time window. A combination of the peak and the width may also be used and is compared with a predetermined threshold. The threshold may be determined based on experiments or tests.

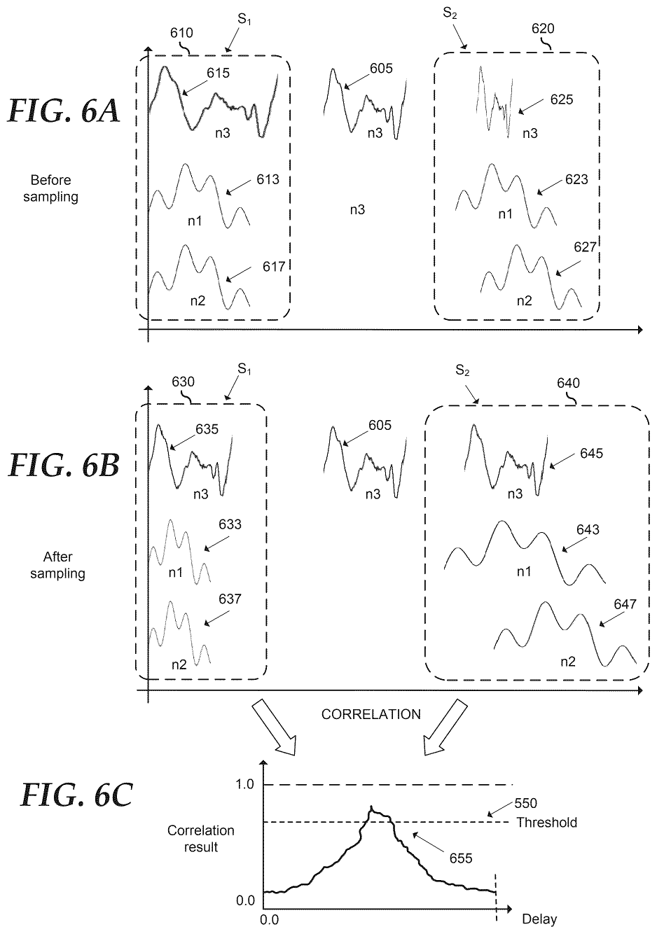

FIGS. 6A, 6B, and 6C show the leak detection result when there is a leak according to an embodiment of the present disclosure. FIG. 6A illustrates the signals before sampling. FIG. 6B illustrates the signals after sampling. FIG. 6C illustrates the correlation result.

In FIG. 6A, the signal S₁ 610 is the sum of the signal n1(2πf) 613, the signal n2(2πf) 617, and the signal n3(2π(f−Δf1) 615 as shown in equation (9). The signal S₂ 620 is the sum of the signal n1(2πf−φ) 523, n2(2πf+φ) 527, and n3(2π(f+Δf1) as shown in equation (10). As in the previous case, n1 and n2 in S₁(t) and S₂(t) differ mainly by a phase shift and therefore their shapes are essentially the same. In other words, they are still correlated. However, n3 in S₁(t) is markedly different from n3 in S₂(t) due to the Doppler effect: n3 in S₁(t) is stretched out while n3 in S₂(t) is compressed. They are in essence uncorrelated.

In FIG. 6B, the signal S₁ 630 is the sum of the signals n1(2π(f+Δf)) 633, n2(2π(f+Δf)) 637, and n3(2πf) 635 as shown in equation (11). Due to the sampling by s₁, the signals n1(2π(f+Δf)) and n2(2π(f+Δf)) are compressed while the signal n3(2πf) returns to the original form. The signal S₂ 640 is the sum of the signals n1(2π(f−Δf)−φ) 643, n2(2π(f−Δf)+φ) 647, and n3(2πf) 645 as shown in equation (12). Due to the sampling by s₂, the signals n1(2π(f−Δf)−φ) and n2(2π(f−Δf)+φ) are stretched. Therefore, n1(2πf) and n1(2π(f−Δf)−φ) have markedly different shapes and therefore they are uncorrelated. Similarly, n2(2πf) and n2(2π(f−Δf)+φ) have markedly different shapes and therefore they are uncorrelated. In contrast, the signals n3(2πf) 635 and n3(2πf) 645 are almost identical and therefore are highly correlated.

In FIG. 6C, the correlation between S₁ 630 and S₂ 640 is calculated over a sliding window and the result is compared with a threshold 550. The ordinate or vertical axis represents the correlation value. The abscissa or horizontal axis represents the delay between the two microphones. The threshold 550 is a predetermined value that may be obtained through experiments and/or tests. The correlation result is a signal 655 with a very high value, exceeding the threshold 550. Since the correlation is higher than the threshold, the leak detector declares that there is a leak and an alert is sent.

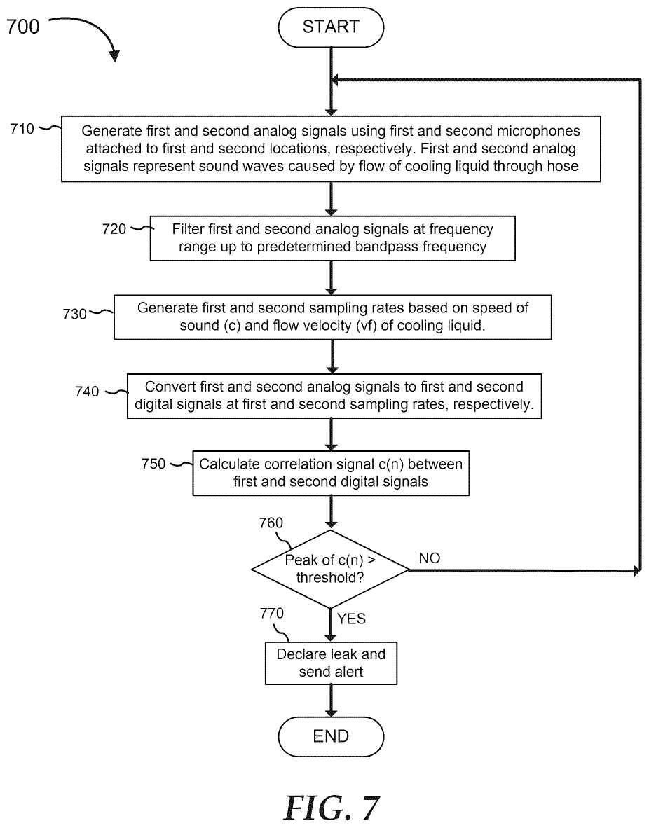

FIG. 7 shows a process 700 for acoustic leak detection according to an embodiment of the present disclosure. Upon START, the process 700 generates first and second analog signals using first and second microphones attached to first and second locations, respectively (Block 710). First and second analog signals represent sound waves caused by flow of cooling liquid through hose. Next, the process 700 filters first and second analog signals at frequency range up to predetermined bandpass frequency (Block 720). This bandpass filtering is to ensure that noise signals outside the frequency range of the sound waves are suppressed. In one embodiment, the band-limited frequency is 5 KHz. Then, the process 700 generates first and second sampling rates based on the speed of sound (c) and the flow velocity (vf) of the cooling liquid (Block 730). The sampling rates may be determined according to equations (1) and (2). Next, the process 700 converts the first and second analog signals to the first and second digital signals at the first and second sampling rates, respectively (Block 740). Then, the process 700 calculates the correlation signal between the first and second digital signals (Block 750).

Next, the process 700 performs leak detection by determining if the peak of the correlation signal c(n) is greater than the predetermined threshold (Block 760). The detection may include other considerations including the width of the correlation signal c(n) as described above. If the peak of the correlation signal c(n) is not greater than the predetermined threshold, there is no leak and the process 700 returns to block 710 to continue monitoring the leak condition. Otherwise, the process 700 declares there is leak and sends an alert (Block 770) and is then terminated.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. An apparatus comprising:
a first microphone attached to a first location on a hose transporting cooling liquid and configured to generate a first analog signal;
a second microphone attached to a second location on the hose and configured to generate a second analog signal; and
a signal processing circuit coupled to the first and second microphones and configured to detect a leak on the hose between the first and second locations based on a correlation signal between the first and second analog signals over a time window,
wherein the first and second analog signals represent sound waves caused by the leak and flow of the cooling liquid through the hose at the first and second locations.

2. The apparatus of claim 1 wherein the signal processing circuit comprises:
an analog-to-digital converter (ADC) configured to convert the first and second analog signals to first and second digital signals at first and second sampling rates, respectively; and
a sampling clock generator configured to generate the first and second sampling rates based on a speed of sound (c) and a flow velocity (vf) of the cooling liquid.

3. The apparatus of claim 2,
wherein the first sampling rate is approximately equal to a reference sampling rate weighed by a first factor equal to (c−vf)/(c+vf), and
wherein the second sampling rate is approximately equal to the reference sampling rate weighed by a second factor equal to (c+vf)/(c−vf).

4. The apparatus of claim 1 wherein the signal processing circuit further comprises
a correlator configured to calculate the correlation signal over the time window.

5. The apparatus of claim 1 wherein the signal processing circuit comprises:
a bandpass filter to filter the first and second analog signals at a bandpass frequency range up to a predetermined bandpass frequency.

6. The apparatus of claim 3 wherein the signal processing circuit further comprises:
a processor; and
a memory coupled to the processor to store instructions that, when executed by the processor, cause the processor to perform operations comprising:
calculating the correlation signal between the first and second digital signals over the time window,
comparing a peak of the correlation signal with a predetermined threshold to generate a comparison result, and
detecting the leak based on the comparison result.

7. The apparatus of claim 6 wherein detecting the leak comprises:
detecting the leak when a combination of a peak magnitude and a peak width exceeds the predetermined threshold.

8. The apparatus of claim 6 wherein the operations further comprise:
post processing the correlation signal.

9. The apparatus of claim 8 wherein post processing comprises:
smoothing the correlation signal to reduce noise.

10. The apparatus of claim 4 wherein the correlator calculates the correlation signal using Fast Fourier Transform.

11. A method comprising:
generating first and second analog signals using first and second microphones attached to first and second locations, respectively, on a hose that transports cooling liquid, the first and second analog signals representing sound waves caused by a leak and flow of the cooling liquid through the hose; and
detecting the leak on the hose between the first and second locations based on a correlation signal between the first and second analog signals over a time window.

12. The method of claim 11 wherein detecting the leak comprises:
generating first and second sampling rates based on a speed of sound (c) and a flow velocity (vf) of the cooling liquid; and
converting the first and second analog signals to first and second digital signals at the first and second sampling rates, respectively.

13. The method of claim 12,
wherein the first sampling rate is approximately equal to a reference sampling rate weighed by a first factor equal to (c−vf)/(c+vf), and
wherein the second sampling rate is approximately equal to the reference sampling rate weighed by a second factor equal to (c−vf)/(c+vf).

14. The method of claim 11 further comprising:
filtering the first and second analog signals at a frequency range up to a predetermined bandpass frequency.

15. The method of claim 12 wherein detecting the leak further comprises:
calculating the correlation signal between the first and second digital signals,
comparing a peak of the correlation signal with a predetermined threshold to generate a comparison result, and
detecting the leak based on the comparison result.

16. The method of claim 16 wherein detecting the leak further comprises:
detecting the leak when a combination of a peak magnitude and a peak width exceeds the predetermined threshold.

17. The method of claim 15 wherein detecting the leak further comprises:
post processing the correlation signal.

18. The method of claim 17 wherein post processing comprises:
smoothing the correlation signal to reduce noise.

19. The method of claim 15 wherein calculating the correlation signal comprises calculating the correlation signal using Fast Fourier Transform.

20. An information handling system, comprising:
a hose that transports cooling liquid to sites in a computing environment; and
a leak detector comprising:
a first microphone attached to a first location on a hose transporting cooling liquid through the sites and configured to generate a first analog signal;
a second microphone attached to a second location on the hose and configured to generate a second analog signal; and
a signal processing circuit coupled to the first and second microphones and configured to detect a leak on the hose between the first and second locations based on a correlation signal between the first and second analog signals over a time window,
wherein the first and second analog signals represent sound waves caused by the leak and flow of the cooling liquid through the hose at the first and second locations.
